(19) United States
(12) Patent Application Publication
(10) Pub. No.: US 2025/0252007 A1
(43) Pub. Date: Aug. 7, 2025

(54) METHOD FOR FAILURE ANALYSIS OF SOLID-STATE DRIVE BASED ON PCIE INTERFACE

(71) Applicant: INNOGRIT TECHNOLOGIES CO., LTD., Shanghai (CN)

(72) Inventors: Xiaoguo ZHANG, Shanghai (CN); Jie CHEN, Shanghai (CN)

(21) Appl. No.: 19/043,091

(22) Filed: Jan. 31, 2025

(30) Foreign Application Priority Data
Feb. 5, 2024 (CN) 2024101633344

(51) Int. Cl. G06F 11/07

(52) U.S. Cl. CPC G06F 11/079; G06F 11/0772; G06F 11/0778

(57) ABSTRACT

This application relates to the field of solid-state drive technology, and discloses a method for failure analysis of solid-state drive based on PCIe interface and a solid-state drive. The method comprises: writing, by a host, a command containing a predetermined flag to a first designated address in a solid-state drive; monitoring, by a controller of the solid-state drive, the first designated address to determine whether the first designated address has the predetermined flag; in response to the first designated address having the predetermined flag, writing, by the controller, fault information to a second designated address in batches and updating an offset address of corresponding content in a third designated address in the fault information with each write to the second designated address, and then clearing the content in the first designated address; reading, by the host, the second designated address and the third designated address, and writing the fault information in the second designated address to a designated position based on the offset address in the third designated address; and writing, by the controller, an end flag to the third designated address. When the NVMe device cannot be found on the host side, the fault information encountered by the customer can be obtained remotely to help analyze, locate and solve the problem.

### CROSS-REFERENCE TO PRIOR APPLICATION

This application claims priority to Chinese Application No. 202410163334.4 filed on Feb. 5, 2024, which is incorporated herein by reference in its entirety.

### TECHNICAL FIELD

This application relates to the field of solid-state drive technology, particularly to a method for failure analysis of PCIe interface based solid-state drive and the solid-state drive.

### BACKGROUND

As software developers of solid-state drives, the main means of locating faults currently are through serial ports or JINK debugging tools. This method is straightforward, efficient, and reliable for internal fault detection by developers. However, in actual usage scenarios, customers may not use external serial ports and debugging tools. Therefore, it is a huge challenge to analyze problems after faults occur in customers side.

Usually, when designing a circuit board, an external serial port and JINK debugging interface are typically implemented to obtain information. If the host can detect the NVMe device normally through the serial port or JLINK debugging tool, the host can obtain some information from the device for fault analysis through vendor defined or NVMe protocol specified commands. However, in most cases where the device fails or cannot be detected by the host, it is currently impossible to obtain additional useful information once the host can no longer find the hard drive device.

The external serial port and JLINK debugging tool are generally used during the development phase and will not be externally connected in mass-produced products due to safety and cost considerations. Manufacturers can obtain debugging information such as logs through customized VSC. Regarding the use of vendor-specific commands (VSC) for problem diagnosis, if the device is lost, it is difficult for the host to obtain useful log information via NVMe commands.

This section aims to provide background or context for the implementation of the application stated in the claims. The description here should not be considered prior art merely because it is included in this section.

### SUMMARY OF THE INVENTION

An object of this application is to provide a method for failure analysis of solid-state drive based on PCIe interface. When the NVMe device cannot be found on the host side, the fault information encountered by the customer can be obtained remotely to assist in diagnosing, locating, and resolving issues.

This application discloses a method for failure analysis of solid-state drive based on PCIe interface, comprising:
writing, by a host, a command containing a predetermined flag to a first designated address in a solid-state drive;
monitoring, by a controller of the solid-state drive, the first designated address to determine whether the first designated address has the predetermined flag;
in response to the first designated address having the predetermined flag, writing, by the controller, fault information to a second designated address in batches and updating an offset address of corresponding content in a third designated address in the fault information with each write to the second designated address, and then clearing the content in the first designated address;
reading, by the host, the second designated address and the third designated address, and writing the fault information in the second designated address to a designated position based on the offset address in the third designated address; and writing, by the controller, an end flag to the third designated address.

In an embodiment, before the host writes the command containing the predetermined flag to the first designated address in the solid-state drive, the method further comprises: reading, by the host, a device classification identifier to identify the solid-state drive.

In an embodiment, before the host writes the command containing the predetermined flag to the first designated address in the solid-state drive, the method further comprises: reading, by the host, a status register of the solid-state drive and determining whether the solid-state drive is ready based on content in the status register.

In an embodiment, the method further comprises: obtaining, by a user, the fault information from the designated position, and analyzing and locating a fault issue based on the fault information.

In an embodiment, the first designated address is CAP_MSI+0xC.

In an embodiment, the second designated address is CAP_MSI+0x8, and the third designated address is CAP_MSI+0x4.

In an embodiment, the controller writes 32 bits to the second designated address in each batch.

The present application also discloses a solid-state drive comprising a controller configured to:
receive, from a host, a command written to a first designated address containing a predetermined flag;
monitor the first designated address to determine whether the first designated address has the predetermined flag;
in response to the first designated address having the predetermined flag, writing fault information to a second designated address in batches and updating an offset address of corresponding content in a third designated address in the fault information with each write to the second designated address, and then clear the content in the first designated address;
receive, from the host, a command to read the second designated address and the third designated address, and return content of the second designated address and the third designated address to the host; and after writing the fault information in the second designated address to a designated position based on the offset address in the third designated address, write an end flag to the third designated address.

In the implementation of this application, by PCIe configuration space related registers, when the NVMe device cannot be found on the host side, the fault information encountered by the customer can be obtained remotely to help analyze, locate and solve the problem.

A large number of technical features are described in the specification of the present application, and are distributed in various technical solutions. If a combination (i.e., a technical solution) of all possible technical features of the present application is listed, the description may be made too long. In order to avoid this problem, the various technical features disclosed in the above summary of the present application, the technical features disclosed in the various embodiments and examples below, and the various technical features disclosed in the drawings can be freely combined with each other to constitute various new technical solutions (all of which are considered to have been described in this specification), unless a combination of such technical features is not technically feasible. For example, feature A+B+C is disclosed in one example, and feature A+B+D+E is disclosed in another example, while features C and D are equivalent technical means that perform the same function, and technically only choose one, not to adopt at the same time. Feature E can be combined with feature C technically. Then, the A+B+C+D scheme should not be regarded as already recorded because of the technical infeasibility, and A+B+C+E scheme should be considered as already documented.

### BRIEF DESCRIPTION OF THE FIGURES

FIG. 1 is a flowchart of a method for failure analysis of solid-state drive based on PCIe interface according to an embodiment of the present application.

### DETAILED DESCRIPTION

In the following description, numerous technical details are set forth in order to provide the readers with a better understanding of the present application. However, those skilled in the art can understand that the technical solutions claimed in the present application can be implemented without these technical details and various changes and modifications based on the following embodiments.

### Explanation of Some Concepts:

PCIe (PCI-Express, peripheral component interconnect express) is a high-speed serial computer expansion bus standard.

In order to make the objects, technical solutions and advantages of the present application clearer, embodiments of the present application will be further described in detail below with reference to the accompanying drawings.

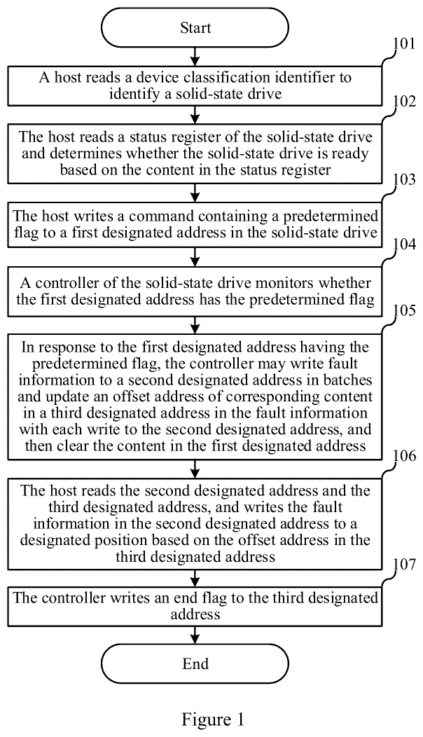

The first embodiment of the present application relates to a method for failure analysis of solid-state drive based on PCIe interface, the process of which is shown in FIG. 1, and the method comprises the following steps:

Step 101, a host reads a device classification identifier to identify a solid-state drive.

Step 102, the host reads a status register of the solid-state drive and determines whether the solid-state drive is ready based on the content in the status register.

Step 103, the host writes a command containing a predetermined flag to a first designated address in the solid-state drive.

Step 104, a controller of the solid-state drive monitors whether the first designated address has the predetermined flag.

Step 105, in response to the first designated address having the predetermined flag, the controller may write fault information to a second designated address in batches and update an offset address of corresponding content in a third designated address in the fault information with each write to the second designated address, and then clear the content in the first designated address.

Step 106, the host reads the second designated address and the third designated address, and writes the fault information in the second designated address to a designated position based on the offset address in the third designated address.

Step 107, the controller writes an end flag to the third designated address.

Then, the user retrieves fault information from the designated position and helps analyze, locate, and solve the problem based on the fault information.

This application leverages registers in the PCIe configuration space to obtain log information by means of a specified protocol, and uses MSI to describe symbol register. This method relies on the mutual cooperation of host tool and firmware. Specifically, the method for failure analysis of solid-state drive based on PCIe interface in this application is implemented as follows:
(1) The host tool reads the device classification identifier and identifies NVMe solid-state drive device.
(2) The host tool reads the status register that indicates the state of the NVMe device controller to determine whether the device is ready.
(3) The host tool writes a 16-bit command (including fixed flag bit) to the address CAP_MSI+0xC.
(4) The hard disk firmware monitors the 0xC address. Once the flag bit is updated, it starts to parse the command and provide fault information (including logs, preset registers, etc.), writes it to the CAP_MSI+0x8 address, updates the offset address to CAP_MSI+0x4, and then clears the CAP_MSI+0xC address. The fault information is transmitted in batches and 32 bits are transmitted each time, and the fault information is written to CAP_MSI+0x8, and then the offset address of the transmission content in the entire fault information is written to CAP_MSI+0x4, and then the content in 0xC is cleared.
(5) The host tool finds that the data at CAP_MSI+0xC has been cleared, reads CAP_MSI+0x4 and CAP_MSI+0x8, and writes the read information to a file according to the offset address.
(6) Steps (3)-(5) are continuously repeated;
(7) After the debugging information has been transmitted completely, the firmware updates an end flag to CAP_MSI+0x4 to notify the host. Upon receiving the information, the host detects that the information has been transmitted completely and saves the file immediately.
(8) The firmware developer can further analyze and locate problems based on the file obtained in the above steps.

Through this method, when the NVMe device cannot be found by the host side, the fault information encountered by the customer can be obtained remotely, since the SSD locates in the server, the host can remotely log in to the server to obtain the fault information of the faulty SSD and assist in diagnosing, locating, and resolving issues.

The second embodiment of the present application relates to a solid-state drive comprising a controller, the controller is configured to:
receive, from a host, a command written to a first designated address containing a predetermined flag;
monitor the first designated address to determine whether the first designated address has the predetermined flag;
in response to the first designated address having the predetermined flag, writing fault information to a second designated address in batches and updating an offset address of corresponding content in a third designated address in the fault information with each write to the second designated address, and then clear the content in the first designated address;
receive, from the host, a command to read the second designated address and the third designated address, and return content of the second designated address and the third designated address to the host;
after writing the fault information in the second designated address to a designated position based on the offset address in the third designated address, write an end flag to the third designated address.

The first embodiment is a method embodiment corresponding to the present embodiment, and the technical details in the first embodiment can be applied to the present embodiment, and the technical details in the present embodiment can also be applied to the first embodiment.

Correspondingly, the embodiments of the present invention also provide a computer-readable storage medium in which computer-executable instructions are stored. When the computer-executable instructions are executed by a processor, the method embodiments of the present invention are implemented. The computer-readable storage media comprises permanent and non-permanent, removable and non-removable media can be used by any method or technology to implement information storage. Information can be computer-readable instructions, data structures, program modules, or other data. Examples of storage media for computers include, but are not limited to, phase change memory (PRAM), static random access memory (SRAM), dynamic random access memory (DRAM), other types of random access memory (RAM), read-only memory (ROM), electrically erasable programmable read-only memory (EEPROM), flash memory or other memory technologies, read-only optical disc read-only memory (CD-ROM), digital multifunctional optical disc (DVD) or other optical storage, magnetic cartridge tapes, magnetic tape disk storage or other magnetic storage devices, or any other non-transport media that can be used to store information that can be accessed by computing devices. As defined herein, a computer-readable storage medium does not include transient computer-readable media (transitory media), such as modulated data signals and carriers.

In addition, an embodiment of the present invention also provides a solid-state drive, which comprising a memory for storing computer-executable instructions, and a processor; the processor is used to execute the computer-executable in the memory to implement the steps in the above method embodiments. Wherein, the processor may be a Central Processing Unit (referred to as “CPU”), or other general-purpose processors, Digital Signal Processor (referred to as “DSP”), Application Specific Integrated Circuit (referred to as “ASIC”) and so on. The aforementioned memory can be read-only memory (ROM), random access memory (RAM), flash memory (Flash), hard disk or solid-state drive, etc. The steps of the method disclosed in various embodiments of the present application may be directly embodied as being performed by a hardware processor, or performed with a combination of hardware and software modules in the processor.

It should be noted that in this specification of the application, relational terms such as the first and second, and so on are only configured to distinguish one entity or operation from another entity or operation, and do not necessarily require or imply any such actual relationship or order between these entities or operations. Furthermore, the term “comprises” or “comprising” or “includes” or any other variations thereof is intended to encompass a non-exclusive inclusion, such that a process, method, article, or device that comprises multiple elements include not only those elements but also other elements, or elements that are inherent to such a process, method, item, or device. Without more restrictions, the element defined by the phrase “comprise(s) a/an” does not exclude that there are other identical elements in the process, method, item or device that includes the element. In this specification of the application, if it is mentioned that an action is performed according to an element, it means the meaning of performing the action at least according to the element, and includes two cases: the action is performed only on the basis of the element, and the action is performed based on the element and other elements. Multiple, repeatedly, various, etc., expressions include 2, twice, 2 types, and 2 or more, twice or more, and 2 types or more types.

All documents mentioned in this specification are considered to be included in the disclosure of this application as a whole, so that they can be used as a basis for modification when necessary. In addition, it should be understood that the above descriptions are only preferred embodiments of this specification, and are not intended to limit the protection scope of this specification. Any modification, equivalent replacement, improvement, etc. made within the spirit and principle of one or more embodiments of this specification should be included in the protection scope of one or more embodiments of this specification.

In some cases, the actions or steps described in the claims can be performed in a different order than in the embodiments and still achieve desired results. In addition, the processes depicted in the drawings do not necessarily require the specific order or sequential order shown in order to achieve the desired results. In some embodiments, multitasking and parallel processing are also possible or may be advantageous.

What is claimed is:

1. A method for failure analysis of solid-state drive based on PCIe interface, comprising:
writing, by a host, a command containing a predetermined flag to a first designated address in a solid-state drive;
monitoring, by a controller of the solid-state drive, the first designated address to determine whether the first designated address has the predetermined flag;
in response to the first designated address having the predetermined flag, writing, by the controller, fault information to a second designated address in batches and updating an offset address of corresponding content in a third designated address in the fault information with each write to the second designated address, and then clearing the content in the first designated address;
reading, by the host, the second designated address and the third designated address, and writing the fault information in the second designated address to a designated position based on the offset address in the third designated address; and
writing, by the controller, an end flag to the third designated address.

2. The method according to claim 1, wherein before the host writes the command containing the predetermined flag to the first designated address in the solid-state drive, further comprising: reading, by the host, a device classification identifier to identify the solid-state drive.

3. The method according to claim 1, wherein before the host writes the command containing the predetermined flag to the first designated address in the solid-state drive, further comprising: reading, by the host, a status register of the solid-state drive and determining whether the solid-state drive is ready based on the content in the status register.

4. The method according to claim 1, further comprising: obtaining, by a user, the fault information from the designated position, and analyzing and locating a fault issue based on the fault information.

5. The method according to claim 1, wherein the first designated address is CAP_MSI+0xC.

6. The method according to claim 1, wherein the second designated address is 0x8 and the third designated address is CAP_MSI+0x4.

7. The method according to claim 1, wherein the controller writes 32 bits to the second designated address in each batch.

8. A solid-state drive comprising a controller, the controller is configured to;
receive, from a host, a command written to a first designated address containing a predetermined flag;
monitor the first designated address to determine whether the first designated address has the predetermined flag;
in response to the first designated address having the predetermined flag, writing fault information to a second designated address in batches and updating an offset address of corresponding content in a third designated address in the fault information with each write to the second designated address, and then clear the content in the first designated address;
receive, from the host, a command to read the second designated address and the third designated address, and return content of the second designated address and the third designated address to the host; and
after writing the fault information in the second designated address to a designated position based on the offset address in the third designated address, write an end flag to the third designated address.
